(19) United States
(12) Patent Application Publication
(10) Pub. No.: US 2007/0019386 A1
(43) Pub. Date: Jan. 25, 2007

(54) Encompassing Heat Sink

(75) Inventor: Matteo B. Gravina, Laredo, TX (US)

Correspondence Address: MATTEO B. GRAVINA, 5835 LONGORIA LOOP, LAREDO, TX, 78041, US

(73) Assignee: Matteo B. Gravina, Laredo, TX (US)

(21) Appl. No.: 11/161,127

(22) Filed: Jul. 24, 2005

(51) Int. Cl. H05K 7/20

(52) U.S. Cl. 361/710

(57) ABSTRACT

This invention relates to a microprocessor heat sink that is place on top of a central processing unit, which at the same time encompasses the sides of the processing unit. It consists of an upper block which receives heat from the processing unit, at the same time the heat sink envelopes the sides of the microprocessor thereby encompassing also its sides. By encompassing the sides of the microprocessor, the heat emitted by the processor are pass along to the heat sinks enveloping arms.

### FIELD OF THE INVENTION

The present invention relates to semiconductor thermal transfer, moreover microprocessor cooling.

### BACKGROUND OF THE INVENTION

The advent of the modern electronics is analogous with computers. The birth of the microprocessor in the 1970's lead to the creation of the modern desktop computer. At its initial creation the Central Processing Unit of the time was a basic mathematical calculating device. With technological growth in the 1980's the first's personal computers came of age, with them faster and more complex microprocessors. With skillful marketing and technology allowing consumers access to computers, micro processing capabilities would be forced to new heights. The initial processing was 4-bit, then came the 8-bit, 16-bit, which has mature to the modern 32-bit processing units. With this eventual growth the microprocessor has mature into a very complex very large scale integration device.

With exceptional growth in software, hardware, and the internet, the demands force on a processing unit are ever more demanding. This accelerated growth has lead to high heat dissipation from microprocessor force to processes millions even billions of calculations per second. Heat emitted by the microprocessor has become a problem forcing manufactures to device solutions. Heat accumulation has lead to thermal conductivity in and around the working parameter of the microprocessor. This has lead to software problems as heat accumulation deters processing abilities to work. The energy consume in today's CPU's is more than a modern light bulb. The energy consume is reradiated back into its surrounding areas by means of conduction, convection, and eventually through radiation.

Various methods for cooing a microprocessor has lead to the use of fanning, heat sinks, and combination of both. The use of heat sinks is a practical method of permitting heat to sink through a metallic arrangement. The heat emitted by the CPU is transfer by means of conductivity through the heat sink. Although the most common approach to transfer heat emitted by a CPU, the use of placing a heat sink on top of a CPU does not receives all the heat emitted by a CPU. The use of fanning is a practical approach widely use. Small fans force cool air throughout the system and into the pathway of the CPU. Even with the use of fans to actively force heat away from the source they nonetheless emit only the heat transfer into the heat sink, and not all the heat created by the CPU. The use of both heat sinks and fans together is the common way for keeping a microprocessor cool, or at room temperature.

Other approaches to other than fanning and heat sink use are the use of solutions, fluids, and eventual air conditioned air. The use of solutions is commonly use in juncture with heat sinks, whereby the solution creates a medium of heat transfer for the upper section of the CPU and a heat sink. Even with high efficient heat transfer qualities of solutions, they nevertheless form a very limited role in heat dissipation. Apart from this method the use of control liquid transfer from a radiator type heat sink to another looping device is another suitable approach. Although the use of liquids to transfer heat is not a novel idea, a possible leak can be disastrous to surrounding working electronics.

The eventual continual growth of microprocessor capabilities clearly dictates parallel growth in heat dissipation problems. The newly introduction of 64-bit microprocessor's into the consumer market is an indication of higher energy consumption by CPU's. Even with designing ducts, heat sinks, fans, the previous approaches mention will become obsolete or shrink in percentage in approach of heat extraction. Forthcoming microprocessor technologies emphasis new approaches in heat extraction capabilities.

### SUMMARY OF THE INVENTION

The present invention is an improvement of modern central processor unit heat sink. The present invention overcomes an often left out objective of present day use of metallic heat sinks use in the extraction of accumulated heat energy of a central processor. As with other heat sinks the present invention extracts heat from the processor by conduction of heat energy from the upper part of central processor chip housing. This surface area is the usual target area of heat extraction. Although employing the same thermal mechanics use previously the present invention further emphasizes the use of the ceramic side housing that houses the microchip. The square area on a modern central processing unit can be from 10% to 15% of the area in proportion to the upper section housing.

The application of the use of a heat sink encompassing the side of a microprocessor aids in the further extraction of heat energy from a processing unit, by means of conduction, convection, and radiation as well. The use of the present invention further advances the thermal heat extraction efficiency by employing the use of side heat extraction design on a heat sink. This mechanism employs the means of extracting an additional thermal conductivity by means of conduction. The conducting matter of the heat sink draws in heat energy that would otherwise prolong in and around the central processor unit. Furthermore employment of side heat extraction lessens the convective energy to stay resident. Thereby the heat energy otherwise staying resident does not move by means of convection onto the surrounding areas of the CPU. As with matter that sustains heat energy, furthermore the resiliency of the working mechanics of the heat sink lessens also the movement of heat energy by means of radiation. Since the air is constantly moving throughout the surrounding areas of the CPU close components inside the computer are susceptible of receiving radiation heat energy.

Furthermore the use of a more efficient heat sink lessens the inefficiency of software working parameters. The ability of the operating system as well as applications are dependent on the CPU, the microprocessor must work in optimal efficiency. By working cooler the microprocessor is thereby able to execute orders and operations requested by the computer operating system and applications as well. By working in a more efficient manner the software applications allow requests and executions which are time sensitive to some applications.

Furthermore the more heat the heat sink is able to extract the less heat energy stays resident in the CPU. The fewer struggles the microprocessor does in executing orders and requests from open applications. Thereby the operating system and open software applications are able to make hardware to operate to OEM specifications. By working to OEM specifications hardware devices execute operations close to specifications. This includes hardware such as monitor, drives, video and audio cards, besides other devices which consumers and businesses integrate into their systems.

Furthermore the more heat energy the heat sink is able to extract and the less heat energy stays resident the operating system and applications are able to execute orders and requests. This includes and is not limited to connected and interconnected devices to a computer. This includes such devices as printers, scanners, plotters, other computers, internet, modems, radio devices, multimedia devices . . . therefore the more heat is extracted by the heat sink the less struggle is enforce to the CPU, thereby collaborate with connected and interconnected devices up to OEM specification.

### DETAILED DESCRIPTION OF THE INVENTION

FIG. 1 is a side view of the encapsulating heat sink on top of a microprocessor. The encapsulating heat sink is device by its (1) main body which receives most convection radiation of heat energy. To the left side in the corner a cutout view of the (2) depression is view, at the end is the (3) encapsulating arm which receives convective energy that would otherwise prolong at the CPU. The encapsulating heat sink has on top an assortment of (4) grills which permit air passage to cool the heat sink. At the bottom of FIG. 3 is the microprocessor which is retains within the central processor chip inside, its typical design is encapsulation of the microprocessor chip by an (5) CPU ceramic protection. At the center is lies the microchip which is usually protected by a (7) microprocessor chip housing. At surrounding attach to the (5) CPU ceramic protection are (6) Ziff socket pins.

In FIG. 2 is the encapsulating heat sink with a partial view. The exploded insertion illustrates a close-up view of the (1) main body, the (2) depression, the (3) encapsulating arm that receives radiation heat from the sides of the (5) CPU ceramic protection. Atop of the exploded view are the (4) grills. Not viewable in FIG. 2 are the bottom section of the encapsulating heat sink. FIG. 4 illustrates this section whereby the full extent of the (3) encapsulating arm is view, follow by the (8) depression main body. Together the (3) encapsulating arm and the (8) depression main body receives heat energy emitted by the top of the central processing unit (5) CPU ceramic protection housing.

In FIG. 3 is an illustration of the heat sink on top of a microprocessor. Beneath them lies typical microprocessor socket and board. At the top is the heat sink with its (4) grill which resides on top of the (1) main body. FIG. 3 illustrates also a sectional view of the (2) depression along with the (3) encapsulating arm. The microprocessor is the same as in other figures. It is composed of the (5) CPU ceramic protection that in turn houses the (7) microprocessor chip housing. On the bottom sides of the central processor unit are the (6) Ziff socket pins. The (6) Ziff socket pins are use to insert on top of the (9) zero inline socket, which is in turn resides on a typical (10) motherboard. Last in FIG. 5 is an illustration of how the working parameters of the invention work. It show how a typical heat sink works and how what otherwise heat radiation energy loss would dissipate, it is capture by the encapsulating heat sink and dissipated through its structure. In FIG. 5 the diagram show how heat energy is capture from the top and the sides of the microprocessor unit by the encapsulating heat sink and is dissipated by fanning and other means typically used.

### BRIEF DESCRIPTION OF THE DRAWINGS

FIG. 1 Is a side view of the present invention;

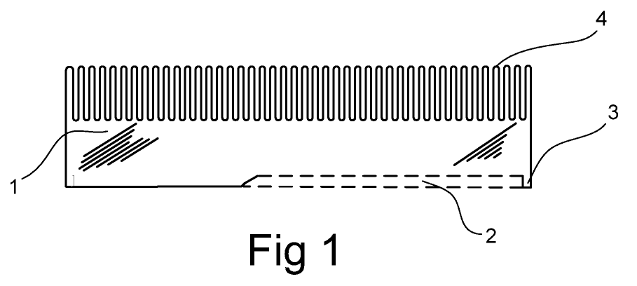

FIG. 2 Is a sectional view of the a corner of the present invention;

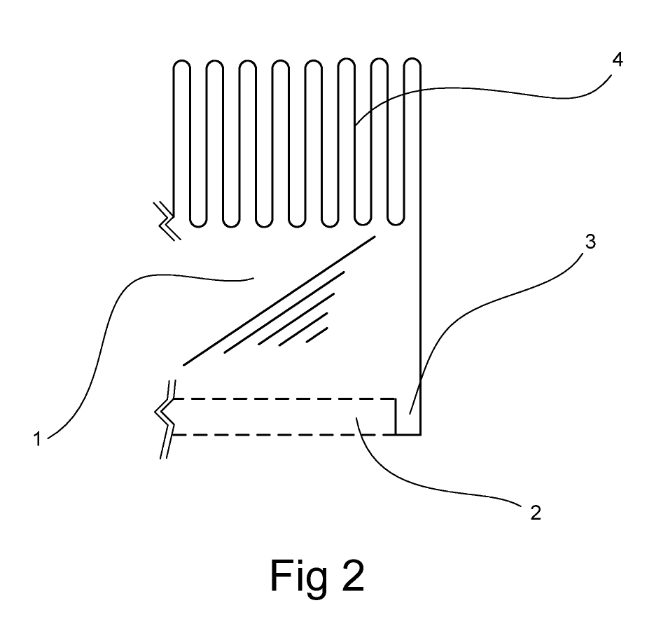

FIG. 3 Is a view of the present invention above a central processing unit which is also above a Ziff Socket;

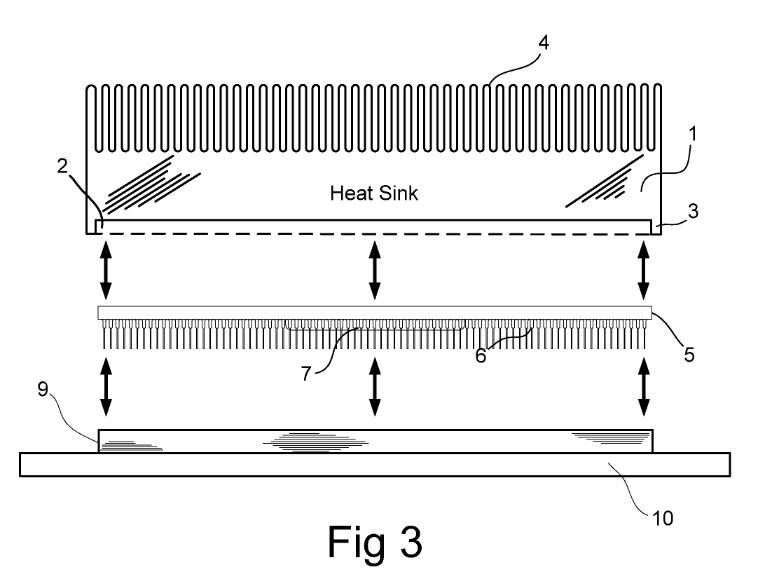

FIG. 4 Is a view of the bottom of the present invention, and

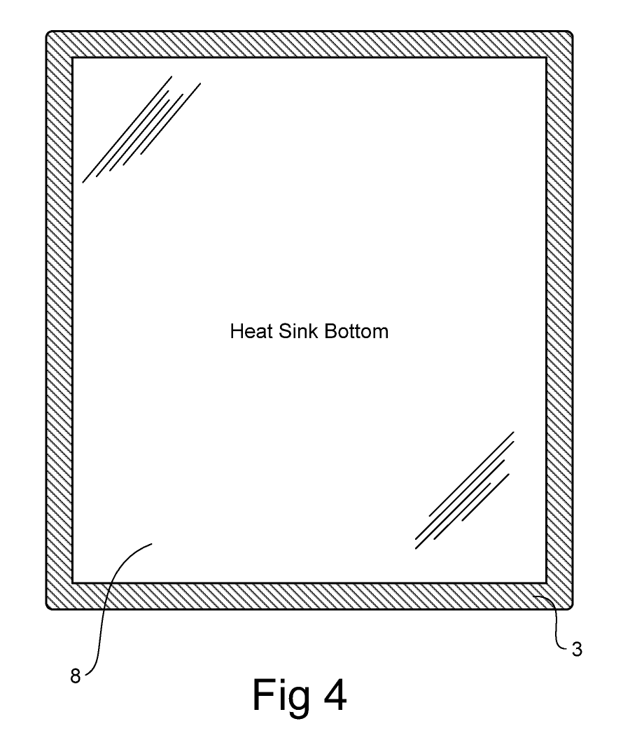

FIG. 5 Is a flow diagram view of how the present invention operates.

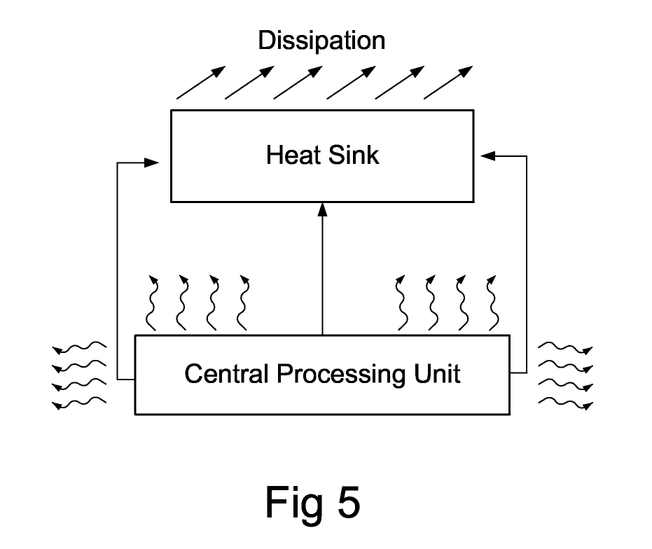

What is claimed is:

1. A heat exchanger embodied by three sections forming uniformity in heat transfer mechanism for integrated semiconductors, more precisely for mounting on microprocessors and the like. Three sections of the heat exchanger are design to use all of the heat emanating from semiconductors and the like. The lower level forms an encompassing loop. The middle section holds of heat receive from lower level. The top body grills section receives the heat from middle section.

2. A heat exchanger according to claim 1, wherein the middle section receives transmitted heat energy by a heat sink bottom receiving the bulk of the radiated heat energy by the integrated semiconductor.

3. A heat exchanger according to claim 1, wherein the middle section receives transmitted heat energy by a heat sink encompassing loop.

4. A heat exchanger embodied by three sections forming uniformity in heat transfer mechanism for integrated semiconductors, more precisely for mounting on microprocessors and the like. Three sections of the heat exchanger are design to use all of the heat emanating from semiconductors and the like. The lower level forms an encompassing loop. The middle section keep holds of heat receive from lower level. The top body grills section which receives the heat from middle section.

5. A heat exchanger according to claim 4, wherein the middle section aids the bottom section by retransmitting heat energy to the upper body grill.

6. A heat exchanger according to claim 4, wherein the middle section aids the lower level by retransmitting heat energy from the encompassing loop to the upper body grill.

7. A heat exchanger embodied by three sections forming uniformity in heat transfer mechanism for integrated semiconductors, more precisely for mounting on microprocessors and the like. Three sections of the heat exchanger are design to use all of the heat emanating from semiconductors and the like. The lower level forms an encompassing loop. The middle section keep holds of heat receive from lower level. The top body grills section which receives the heat from middle section.

8. A heat exchanger according to claim 7, wherein the top body grills section receives heat energy from the middle section, thereby transmitting it by air flow by means of mechanical transmission.
